(19) United States
(12) Patent Application Publication
(10) Pub. No.: US 2026/0319300 A1
(43) Pub. Date: Oct. 15, 2026

(54) ACTIVE MATRIX SUBSTRATE AND LIQUID CRYSTAL DISPLAY DEVICE INCLUDING THE SAME

(71) Applicant: SHARP KABUSHIKI KAISHA, Sakai City (JP)

(72) Inventor: KATSUNORI MISAKI, Sakai City (JP)

(21) Appl. No.: 19/554,829

(22) Filed: Mar. 3, 2026

(30) Foreign Application Priority Data
Apr. 15, 2025 (JP) 2025-066905

(51) Int. Cl. G02F 1/1362; G02F 1/1368; H10D 86/40; H10D 86/60

(52) U.S. Cl. CPC G02F 1/136222; G02F 1/136286; G02F 1/1368; H10D 86/441; H10D 86/60

(57) ABSTRACT

A color filter includes a plurality of first grooves formed to correspond to a plurality of subpixels arranged in a column direction, an organic resin film includes a plurality of second grooves formed to correspond to a plurality of subpixels arranged in the column direction, in each subpixel, a TFT is electrically connected to the pixel electrode via a first relay electrode provided to reach a base of the corresponding first groove from a base of a contact hole formed in the first inorganic insulating film, and a second relay electrode provided to reach one edge portion of the second groove from the base of the first groove via one sidewall of the first groove and one sidewall of the second groove, and a protrusion protruding toward the one sidewall side of the second groove is provided on the other sidewall of the second groove for each subpixel.

### CROSS-REFERENCE TO RELATED APPLICATIONS

This application claims the benefit of priority to Japanese Patent Application Number 2025-066905 filed on Apr. 15, 2025. The entire contents of the above-identified application are hereby incorporated by reference.

### BACKGROUND

### Technical Field

The disclosure relates to an active matrix substrate and a liquid crystal display device including the active matrix substrate.

In recent years, liquid crystal display devices often use a color filter-on-array (hereinafter also referred to as “COA”) structure in which a color filter is provided on an active matrix substrate (array substrate) and alignment with a counter substrate is not required.

For example, JP 2016-114779 A discloses a liquid crystal display device including an active element substrate including a color filter, a common electrode provided on the color filter, a common wiring line electrically connected to the common electrode, a reflection suppressing film provided on the common wiring line and the color filter, and a pixel electrode generating an electrical field between the common electrode and the pixel electrode.

### SUMMARY

In the active matrix substrate having the COA structure, in consideration of the disturbance of the alignment of a liquid crystal layer, for example, it has been proposed that an electrical connection between a relay electrode electrically connected to a thin film transistor (hereinafter, also referred to as "TFT") and the pixel electrode is performed through a groove formed in a stripe shape in a plan view, not through a contact hole formed in a layered film of a color filter and an organic resin film. However, in the active matrix substrate in which electrical connection is performed through the groove formed in the layered film, a conductive film to be the relay electrode remains at a base of the groove, and the relay electrodes adjacent to each other are short-circuited, or an applied resin film to be the organic resin film remains, and the conduction between the relay electrode and another relay electrode in the lower layer is poor, and thus, the electrical connection to the pixel electrode becomes uncertain.

The disclosure has been made in view of the above-described circumstances, and an object thereof is to reliably perform the electrical connection to the pixel electrode.

In order to achieve the above object, an active matrix substrate according to the disclosure includes a base substrate, a plurality of thin film transistors provided to correspond to a plurality of subpixels arranged in a matrix on the base substrate, a color filter provided on the plurality of thin film transistors with a first inorganic insulating film interposed between the color filter and the plurality of thin film transistors and including a colored layer of a predetermined color disposed to correspond to each subpixel, an organic resin film provided on the color filter, a plurality of pixel electrodes provided on the organic resin film to correspond to the plurality of subpixels, and a common electrode provided on pixel electrodes with a second inorganic insulating film interposed between the common electrode and the pixel electrodes, wherein the color filter includes a plurality of first grooves formed to extend in parallel to each other in the row direction to correspond to a plurality of subpixels arranged in the column direction, the organic resin film includes a plurality of second grooves formed to extend in parallel to each other in a row direction to correspond to a plurality of subpixels arranged in a column direction, in each subpixel, the corresponding thin film transistor is electrically connected to the corresponding pixel electrode via a first relay electrode provided to reach a base of the corresponding first groove from a base of a contact hole formed in the first inorganic insulating film, and a second relay electrode provided to reach one edge portion of the corresponding second groove from the base of the corresponding first groove via one sidewall of the first groove and one sidewall of the corresponding second groove, and a protrusion protruding toward the one sidewall side of the second groove is provided on the other sidewall of the second groove for each subpixel.

Further, according to the disclosure, there is provided a liquid crystal display device including the above-described active matrix substrate, a counter substrate facing the active matrix substrate, and a liquid crystal layer provided between the active matrix substrate and the counter substrate.

According to the disclosure, the electrical connection to the pixel electrode can be reliably performed.

### BRIEF DESCRIPTION OF DRAWINGS

The disclosure will be described with reference to the accompanying drawings, wherein like numbers reference like elements.

FIG. 1 is a plan view of an active matrix substrate according to a first embodiment of the disclosure.

FIG. 2 is a cross-sectional view of the active matrix substrate and the liquid crystal display device including the active matrix substrate. The cross-sectional view is taken along a line II-II in FIG. 1.

FIG. 3 is a first cross-sectional view illustrating a part of a manufacturing method of the active matrix substrate according to the first embodiment of the disclosure.

FIG. 4 is a second cross-sectional view subsequent to FIG. 3, illustrating a state after a part of the manufacturing method of the active matrix substrate according to the first embodiment of the disclosure.

FIG. 5 is a third cross-sectional view subsequent to FIG. 4, illustrating a state after a part of the manufacturing method of the active matrix substrate according to the first embodiment of the disclosure.

FIG. 6 is a fourth cross-sectional view subsequent to FIG. 5, illustrating a state after a part of the manufacturing method of the active matrix substrate according to the first embodiment of the disclosure.

FIG. 7 is a fifth cross-sectional view subsequent to FIG. 6, illustrating a state after a part of the manufacturing method of the active matrix substrate according to the first embodiment of the disclosure.

FIG. 8 is a sixth cross-sectional view subsequent to FIG. 7, illustrating a state after a part of the manufacturing method of the active matrix substrate according to the first embodiment of the disclosure.

FIG. 9 is a seventh cross-sectional view subsequent to FIG. 8, illustrating a state after a part of the manufacturing method of the active matrix substrate according to the first embodiment of the disclosure.

FIG. 10 is an eighth cross-sectional view subsequent to FIG. 9, illustrating a state after a part of the manufacturing method of the active matrix substrate according to the first embodiment of the disclosure.

FIG. 11 is a ninth cross-sectional view subsequent to FIG. 10, illustrating a state after a part of the manufacturing method of the active matrix substrate according to the first embodiment of the disclosure.

FIG. 12 is a tenth cross-sectional view subsequent to FIG. 11, illustrating a state after a part of the manufacturing method of the active matrix substrate according to the first embodiment of the disclosure.

FIG. 13 is an eleventh cross-sectional view subsequent to FIG. 12, illustrating a state after a part of the manufacturing method of the active matrix substrate according to the first embodiment of the disclosure.

FIG. 14 is a twelfth cross-sectional view subsequent to FIG. 13, illustrating a state after a part of the manufacturing method of the active matrix substrate according to the first embodiment of the disclosure.

FIG. 15 is a thirteenth cross-sectional view subsequent to FIG. 14, illustrating a state after a part of the manufacturing method of the active matrix substrate according to the first embodiment of the disclosure.

FIG. 16 is a fourteenth cross-sectional view subsequent to FIG. 15, illustrating a state after a part of the manufacturing method of the active matrix substrate according to the first embodiment of the disclosure.

FIG. 17 is a plan view of an active matrix substrate according to a second embodiment of the disclosure.

FIG. 18 is a cross-sectional view of the active matrix substrate taken along a line XVIII-XVIII in FIG. 17.

FIG. 19 is a first cross-sectional view illustrating a part of a manufacturing method of the active matrix substrate according to the second embodiment of the disclosure.

FIG. 20 is a second cross-sectional view subsequent to FIG. 19, illustrating a state after a part of the manufacturing method of the active matrix substrate according to the second embodiment of the disclosure.

FIG. 21 is a third cross-sectional view subsequent to FIG. 20, illustrating a state after a part of the manufacturing method of the active matrix substrate according to the second embodiment of the disclosure.

FIG. 22 is a fourth cross-sectional view subsequent to FIG. 21, illustrating a state after a part of the manufacturing method of the active matrix substrate according to the second embodiment of the disclosure.

FIG. 23 is a fifth cross-sectional view subsequent to FIG. 22, illustrating a state after a part of the manufacturing method of the active matrix substrate according to the second embodiment of the disclosure.

FIG. 24 is a sixth cross-sectional view subsequent to FIG. 23, illustrating a state after a part of the manufacturing method of the active matrix substrate according to the second embodiment of the disclosure.

FIG. 25 is a seventh cross-sectional view subsequent to FIG. 24, illustrating a state after a part of the manufacturing method of the active matrix substrate according to the second embodiment of the disclosure.

FIG. 26 is an eighth cross-sectional view subsequent to FIG. 25, illustrating a state after a part of the manufacturing method of the active matrix substrate according to the second embodiment of the disclosure.

FIG. 27 is a ninth cross-sectional view subsequent to FIG. 26, illustrating a state after a part of the manufacturing method of the active matrix substrate according to the second embodiment of the disclosure.

FIG. 28 is a tenth cross-sectional view subsequent to FIG. 27, illustrating a state after a part of the manufacturing method of the active matrix substrate according to the second embodiment of the disclosure.

FIG. 29 is an eleventh cross-sectional view subsequent to FIG. 28, illustrating a state after a part of the manufacturing method of the active matrix substrate according to the second embodiment of the disclosure.

FIG. 30 is a twelfth cross-sectional view subsequent to FIG. 29, illustrating a state after a part of the manufacturing method of the active matrix substrate according to the second embodiment of the disclosure.

FIG. 31 is a plan view of an active matrix substrate according to a third embodiment of the disclosure.

### DESCRIPTION OF EMBODIMENTS

Embodiments of a technique according to the disclosure will be described below in detail with reference to the drawings. Note that the technique according to the disclosure is not limited to the embodiments to be described below.

### First Embodiment

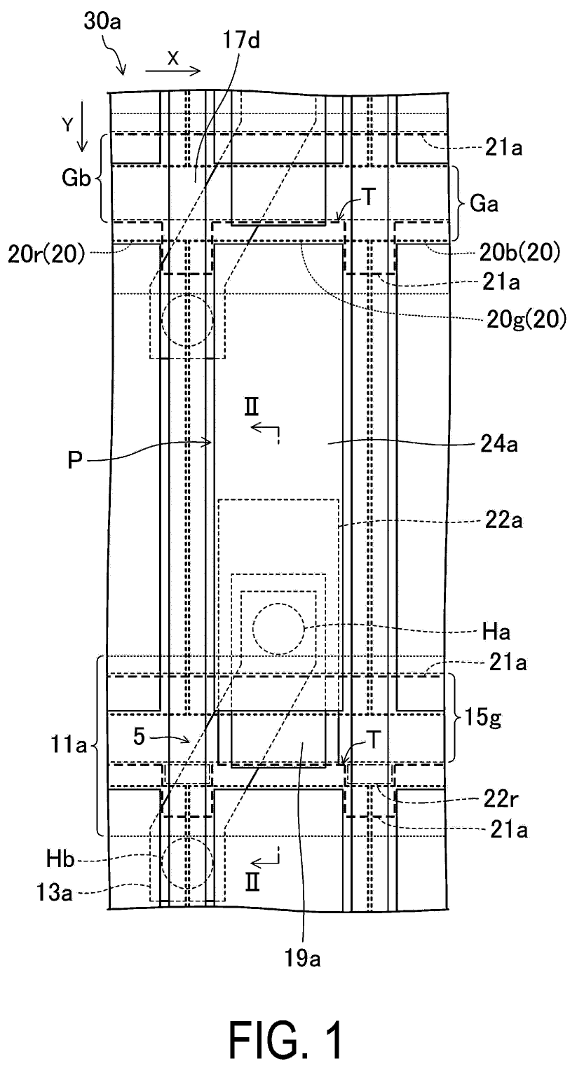

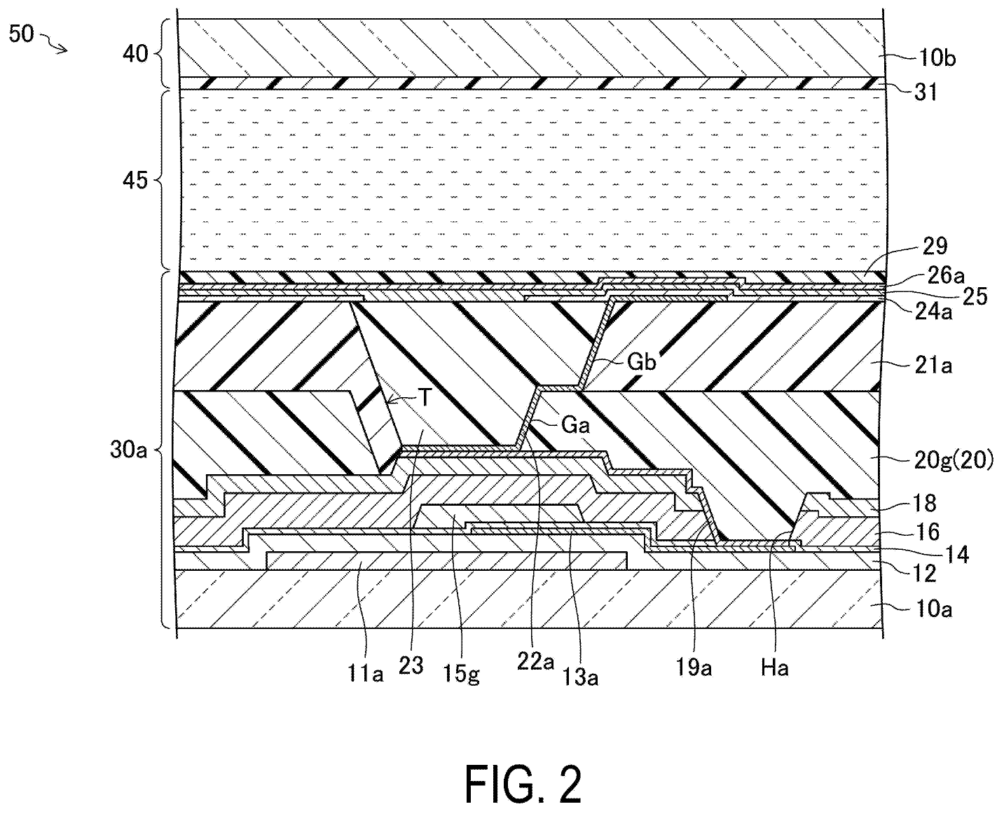

FIGS. 1-16 illustrate a first embodiment of a liquid crystal display device according to the disclosure. FIG. 1 is a plan view of an active matrix substrate 30a according to the present embodiment. FIG. 2 is a cross-sectional view of the active matrix substrate 30a and a liquid crystal display device 50 including the active matrix substrate 30a taken along a line II-II in FIG. 1.

As illustrated in FIG. 2, the liquid crystal display device 50 includes the active matrix substrate 30a having a COA structure, a counter substrate 40 provided so as to face the active matrix substrate 30a, and a liquid crystal layer 45 provided between the active matrix substrate 30a and the counter substrate 40. In the liquid crystal display device 50, a plurality of subpixels P (see FIG. 1) are provided in a matrix shape in a display region that displays an image. In the display region, as illustrated in FIG. 1, subpixels P for gray scale display of red with red layers 20r, subpixels P for gray scale display of green with green layers 20g, and subpixels P for gray scale display of blue with blue layers 20b are disposed adjacent to each other. Note that in the display region, as described above, one pixel is constituted by three subpixels P adjacent to each other for gray scale display of red, green, and blue. In the active matrix substrate 30a of FIG. 1, as described above, the plurality of subpixels P are provided in the matrix shape, and an X direction in the drawing is a row direction, and a Y direction in the drawing is a column direction.

As illustrated in FIG. 2, the active matrix substrate 30a includes a base substrate 10a such as a glass substrate, a plurality of TFTs 5 provided on the base substrate 10a to correspond to the plurality of subpixels P, a color filter 20 provided on the plurality of TFTs 5 with a first interlayer insulating film 16 and a second interlayer insulating film 18 interposed therebetween, an organic resin film 21a provided on the color filter 20, a plurality of pixel electrodes 24a provided on the organic resin film 21a to correspond to the plurality of subpixels P, a common electrode 26a provided on each pixel electrode 24a with a third interlayer insulating film 25 interposed therebetween, and an alignment film 29 provided on the common electrode 26a. As illustrated in FIG. 1, the active matrix substrate 30a includes, on the base substrate 10a in the display region, a plurality of gate lines 15g provided to extend in parallel to each other in the X direction in the drawing to correspond to the plurality of subpixels P arranged in the Y direction in the drawing, and a plurality of source lines 17d provided to extend in parallel to each other in the Y direction in the drawing to correspond to the plurality of subpixels P arranged in the X direction in the drawing, so as to intersect the gate lines 15g with the first interlayer insulating film 16 (see FIGS. 2-7) interposed therebetween.

As illustrated in FIGS. 1 and 2, the TFT 5 includes a semiconductor layer 13a provided on a base coat film 12, and a gate electrode (15g) provided on the semiconductor layer 13a with a gate insulating film 14 interposed therebetween.

The semiconductor layer 13a is formed of a semiconductor film made of, for example, an In-Ga-Zn-O-based oxide semiconductor. Here, the In-Ga-Zn-O based semiconductor is a ternary oxide of indium (In), gallium (Ga), and zinc (Zn), and a ratio (a composition ratio) of each of In, Ga, and Zn is not particularly limited to a specific value. The In-Ga-Zn-O based semiconductor may be an amorphous semiconductor or may be a crystalline semiconductor. Note that as a crystalline In-Ga-Zn-O based semiconductor, a crystalline In-Ga-Zn-O based semiconductor in which the c-axis is oriented substantially perpendicular to the layer surface is preferable. In place of the In-Ga-Zn-O based semiconductor, another oxide semiconductor may be included. Examples of the other oxide semiconductor may include an In-Sn-Zn-O based semiconductor (for example, In₂O₃-SnO₂-ZnO; InSnZnO). Here, the In-Sn-Zn-O based semiconductor is a ternary oxide of indium (In), tin (Sn), and zinc (Zn). Alternatively, examples of the other oxide semiconductor may include an In-Al-Zn-O based semiconductor, an In-Al-Sn-Zn-O based semiconductor, a Zn-O based semiconductor, an In-Zn-O based semiconductor, a Zn-Ti-O based semiconductor, a Cd-Ge-O based semiconductor, a Cd-Pb-O based semiconductor, cadmium oxide (CdO), a Mg-Zn-O based semiconductor, an In-Ga-Sn-O based semiconductor, an In-Ga-O based semiconductor, a Zr-In-Zn-O based semiconductor, a Hf-In-Zn-O based semiconductor, an Al-Ga-Zn-O based semiconductor, a Ga-Zn-O based semiconductor, an In-Ga-Zn-Sn-O based semiconductor, InGaO₃(ZnO)₅, magnesium zinc oxide (MgₓZn₁₋ₓO), and cadmium zinc oxide (CdₓZn₁₋ₓO). Note that, as the Zn-O based semiconductor, a semiconductor in a non-crystalline (amorphous) state of ZnO to which one kind or a plurality of kinds of impurity elements among group 1 elements, group 13 elements, group 14 elements, group 15 elements, group 17 elements, and the like are added, a semiconductor in a polycrystalline state, a semiconductor in a microcrystalline state in which the non-crystalline state and the polycrystalline state are mixed, or a semiconductor to which no impurity element is added can be used. The semiconductor layer 13a includes a source region and a drain region that are provided so as to be separated from each other, and a channel region provided between the source region and the drain region. Here, the channel region is provided so as to overlap the gate electrode (15g). As illustrated in FIG. 1, the source region is electrically connected to the source line 17d via a second contact hole Hb formed in the gate insulating film 14 and the first interlayer insulating film 16. As illustrated in FIGS. 1 and 2, the drain region is electrically connected to the pixel electrode 24a via a first relay electrode 19a and a second relay electrode 22a, which will be described later. Further, as illustrated in FIGS. 1 and 2, a light blocking layer 11a provided on the base substrate 10a is disposed on the base substrate 10a side of the semiconductor layer 13a with the base coat film 12 interposed therebetween.

As illustrated in FIG. 1, the gate electrode (15g) is formed of a part of the gate line 15g. As described above, the gate electrode (15g) is provided so as to overlap the channel region of the semiconductor layer 13a, and is configured to control conduction between the source region and the drain region of the semiconductor layer 13a.

The base coat film 12, the gate insulating film 14, the first interlayer insulating film 16, the second interlayer insulating film 18, and the third interlayer insulating film 25 are formed of, for example, a single-layer film or a layered film of an inorganic insulating film such as silicon nitride, silicon oxide, or silicon oxynitride. The first interlayer insulating film 16 and the second interlayer insulating film 18 are provided as a first inorganic insulating film. The third interlayer insulating film 25 is provided as a second inorganic insulating film. Note that the base coat film 12 and the gate insulating film 14 on the semiconductor layer 13a side are formed of a silicon oxide film.

The color filter 20 is provided so that a colored layer of a predetermined color is disposed to correspond to each subpixel P. Specifically, as illustrated in FIG. 1, the color filter 20 include the red layer 20r provided as a colored layer in the subpixel P for gray scale display of red, the green layer 20g provided as a colored layer in the subpixel P for gray scale display of green, and the blue layer 20b provided as a colored layer in the subpixel P for gray scale display of blue. The red layer 20r, the green layer 20g, and the blue layer 20b are made of, for example, a transparent organic resin material, such as an acrylic resin colored in a predetermined color. As illustrated in FIGS. 1 and 2, the color filter 20 includes a plurality of first grooves Ga formed so as to extend in parallel to each other in the X direction in FIG. 1 to correspond to the plurality of subpixels P arranged in the Y direction in FIG. 1. Here, as illustrated in FIGS. 1 and 2, each first groove Ga is provided so as to overlap each gate line 15g.

The organic resin film 21a is made of, for example, a transparent organic resin material such as an acrylic resin. As illustrated in FIGS. 1 and 2, the organic resin film 21a includes a plurality of second grooves Gb formed so as to extend in parallel to each other in the X direction in FIG. 1 to correspond to the plurality of subpixels P arranged in the Y direction in FIG. 1. Here, as illustrated in FIGS. 1 and 2, each second groove Gb is provided so as to overlap each gate line 15g. In each subpixel P, as illustrated in FIGS. 1 and 2, the drain region of the semiconductor layer 13a constituting the TFT 5 is electrically connected to the pixel electrode 24a via the first relay electrode 19a provided so as to reach the base of the first groove Ga from the base of a first contact hole Ha formed in the gate insulating film 14 and the first interlayer insulating film 16, and the second relay electrode 22a provided so as to reach one edge portion (on the negative side in the Y direction in FIG. 1) of the second groove Gb from the base of the first groove Ga via one sidewall (on the negative side in the Y direction in FIG. 1) of the first groove Ga and one sidewall (on the negative side in the Y direction in FIG. 1) of the second groove Gb. Here, as illustrated in FIGS. 1 and 2, a protrusion T protruding toward one sidewall side (on the negative side in the Y direction in FIG. 1) of the second groove Gb is provided on the other sidewall (on the positive side in the Y direction in FIG. 1) of the second groove Gb for each subpixel P. As illustrated in FIG. 1, the protrusion T is provided in a wide rectangular protruding shape in a plan view between a pair of source lines 17d adjacent to each other.

As illustrated in FIGS. 1 and 2, in each subpixel P, the pixel electrode 24a is provided in a rectangular shape on the organic resin film 21a, the upper portion of the second relay electrode 22a, and a resin-filled layer 23 formed inside the first groove Ga and the second groove Gb. The pixel electrode 24a constitutes an auxiliary capacity of each subpixel P together with the common electrode 26a and the third interlayer insulating film 25 provided between the pixel electrode 24a and the common electrode 26a.

The common electrode 26a is provided in common to the multiple subpixels P. The common electrode 26a is provided with belt-shaped slits (not illustrated) for aligning the liquid crystal layer 45.

The alignment film 29 and an alignment film 31, which will be described below, are made of, for example, a polyimide resin whose surface is subjected to rubbing.

As illustrated in FIG. 2, the counter substrate 40 includes a base substrate 10b such as a glass substrate, and the alignment film 31 provided on the base substrate 10b.

The liquid crystal layer 45 is made of, for example, a nematic liquid crystal material having electro-optical properties. The liquid crystal layer 45 is sealed between the active matrix substrate 30a and the counter substrate 40 by using a sealing member having a frame-like shape that bonds the active matrix substrate 30a and the counter substrate 40 to each other in a frame region around the display region.

In the liquid crystal display device 50 having the above-described configuration, a predetermined voltage is applied to the auxiliary capacity and the liquid crystal layer 45 disposed between each pixel electrode 24a and the common electrode 26a, and the alignment state of the liquid crystal layer 45 is changed by an electrical field generated in a direction along the surface of the substrate, that is, in a horizontal direction, thereby adjusting the transmittance of light passing through the panel of each subpixel P to display an image.

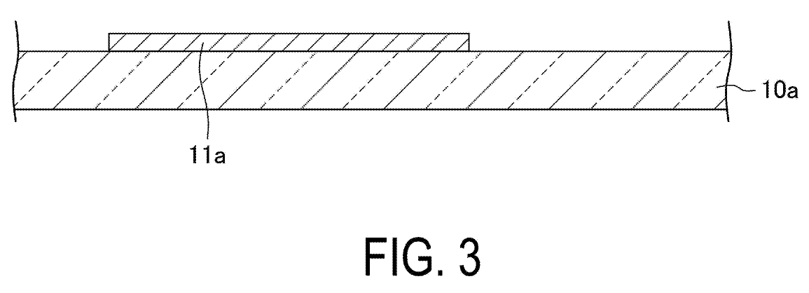

Next, a manufacturing method of the liquid crystal display device 50 according to the present embodiment will be described, focusing on a method of manufacturing the active matrix substrate 30a. FIGS. 3-16 are first to fourteenth cross-sectional views, respectively, sequentially illustrating a part of a manufacturing method of the active matrix substrate 30a.

First, a metal film such as a titanium film (with a thickness of about 50 nm) or the like is formed by, for example, a sputtering method on the base substrate 10a such as a glass substrate, and then the metal film is patterned, thereby forming the light blocking layer 11a or the like, as illustrated in FIG. 3.

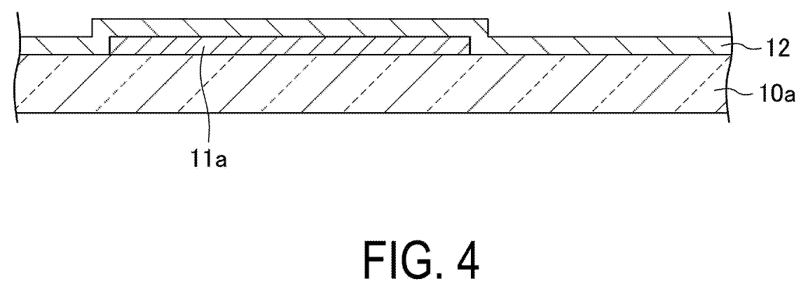

Subsequently, a silicon oxide film (with a thickness of about 100 nm) and the like is formed by, for example, plasma chemical vapor deposition (CVD) on the substrate surface on which the light blocking layer 11a or the like is formed, thereby forming the base coat film 12 as illustrated in FIG. 4.

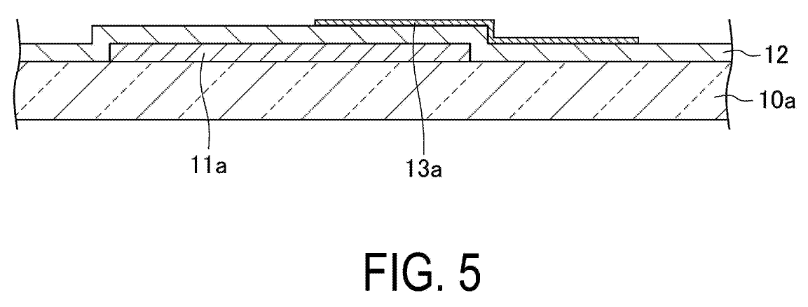

Thereafter, InGaZnO₄ (with a thickness of about 30 nm) or the like is formed by, for example, a sputtering method on the substrate surface on which the base coat film 12 is formed, to form a semiconductor film made of an oxide semiconductor, and then the semiconductor film is patterned, thereby forming the semiconductor layer 13a or the like as illustrated in FIG. 5.

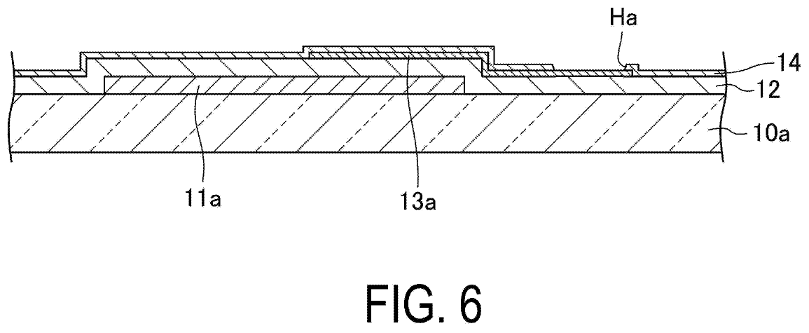

Further, an inorganic insulating film such as a silicon oxide film (with a thickness of about 100 nm) or the like is formed by, for example, plasma CVD on the substrate surface on which the semiconductor layer 13a or the like is formed, and then the inorganic insulating film is patterned, thereby forming the gate insulating film 14 including the first contact hole Ha and the second contact hole Hb (see FIG. 1) as illustrated in FIG. 6.

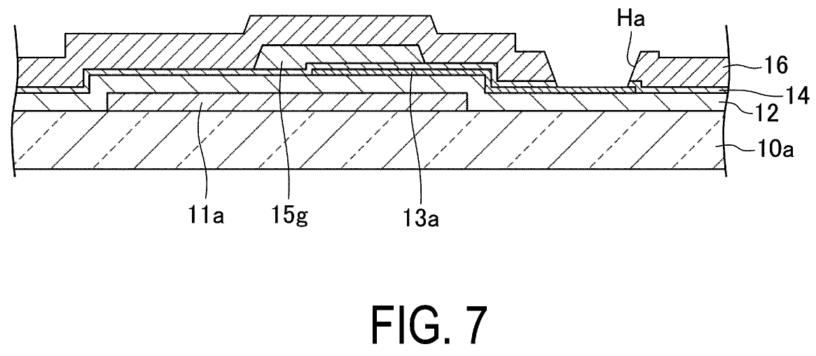

Subsequently, a titanium film (with a thickness of about 50 nm), an aluminum film (with a thickness of approximately 300 nm), and a titanium film (with a thickness of approximately 50 nm) are sequentially formed by, for example, a sputtering method on the substrate surface on which the gate insulating film 14 is formed, to form a metal layered film, and then the metal layered film is patterned, thereby forming the gate line (gate electrode) 15g (see FIG. 7) or the like.

Thereafter, a silicon oxide film (with a thickness of about 300 nm) and a silicon nitride film (with a thickness of about 150 nm) are sequentially formed by, for example, plasma CVD on the substrate surface on which the gate line 15g or the like is formed to form an inorganic insulating layered film, and then the inorganic insulating layered film is patterned, thereby forming the first interlayer insulating film 16 including the first contact hole Ha and the second contact hole Hb (see FIG. 1) as illustrated in FIG. 7.

Further, a titanium film (with a thickness of about 50 nm), an aluminum film (with a thickness of about 300 nm), and a titanium film (with a thickness of about 50 nm) are sequentially formed by, for example, a sputtering method on the substrate surface on which the first interlayer insulating film 16 is formed to form a metal layered film, and then, the metal layered film is patterned, thereby forming the source line 17d or the like.

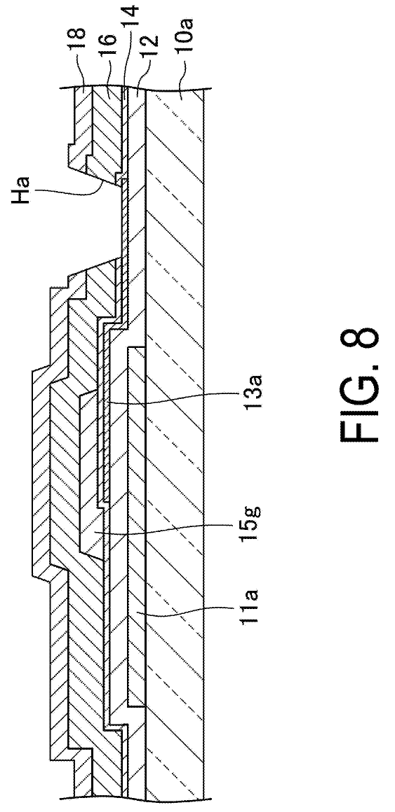

Subsequently, a silicon oxide film (with a thickness of about 300 nm) and a silicon nitride film (with a thickness of about 150 nm) are sequentially formed by, for example, plasma CVD on the substrate surface on which the source line 17d or the like is formed to form an inorganic insulating layered film, and then the inorganic insulating layered film is patterned, thereby forming the second interlayer insulating film 18 including the first contact hole Ha as illustrated in FIG. 8.

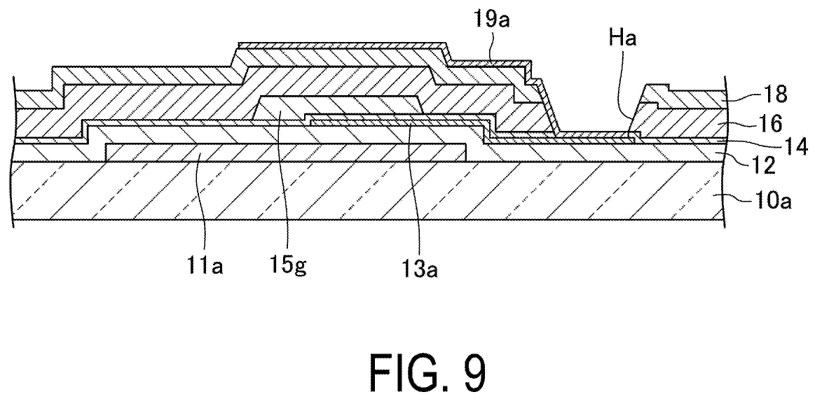

Thereafter, a transparent conductive film such as an indium tin oxide ((hereinafter, also referred to as “ITO”) film (with a thickness of about 100 nm) is formed by, for example, a sputtering method on the substrate surface on which the second interlayer insulating film 18 is formed, and then the transparent conductive film is patterned, thereby forming the first relay electrode 19a or the like as illustrated in FIG. 9.

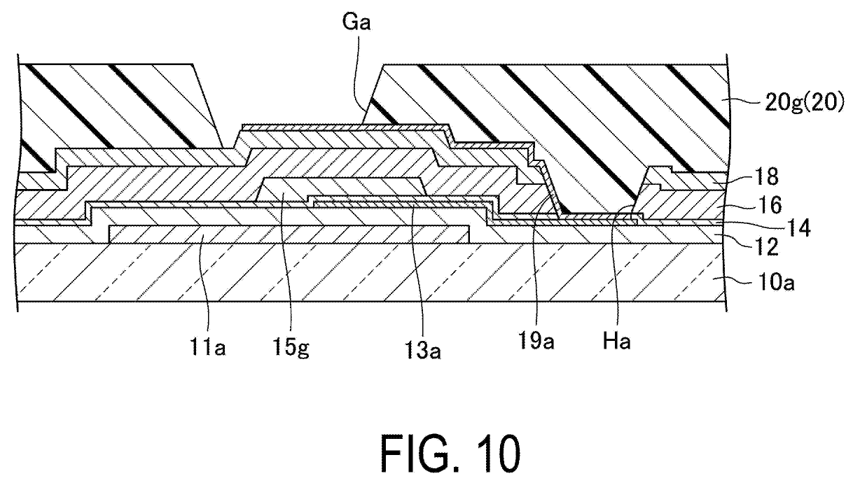

Further, a red, green, or blue colored acrylic photosensitive resin is applied by, for example, spin coating or slit coating to the substrate surface on which the first relay electrode 19a or the like is formed, and the applied photosensitive resin is partially exposed and then patterned by development, thereby forming a colored layer (for example, the red layer 20r) having a selected color with a thickness of about 1.5 μm. Thereafter, the same or a similar step is repeated for the other two colors to form the colored layers of the other two colors (for example, the green layer 20g and the blue layer 20b), thereby forming the color filter 20 including the first groove Ga as illustrated in FIG. 10.

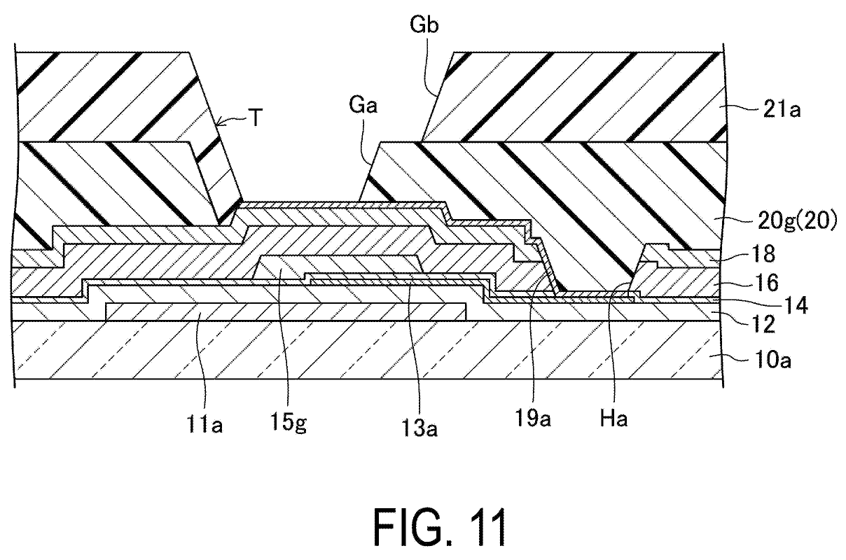

Subsequently, an acrylic photosensitive resin is applied by, for example, spin coating or slit coating to the substrate surface on which the color filter 20 is formed, and the applied photosensitive resin is partially exposed and then patterned by development, thereby forming the organic resin film 21a including the second groove Gb provided with the protrusion T with a thickness of about 2.0 μm as illustrated in FIG. 11.

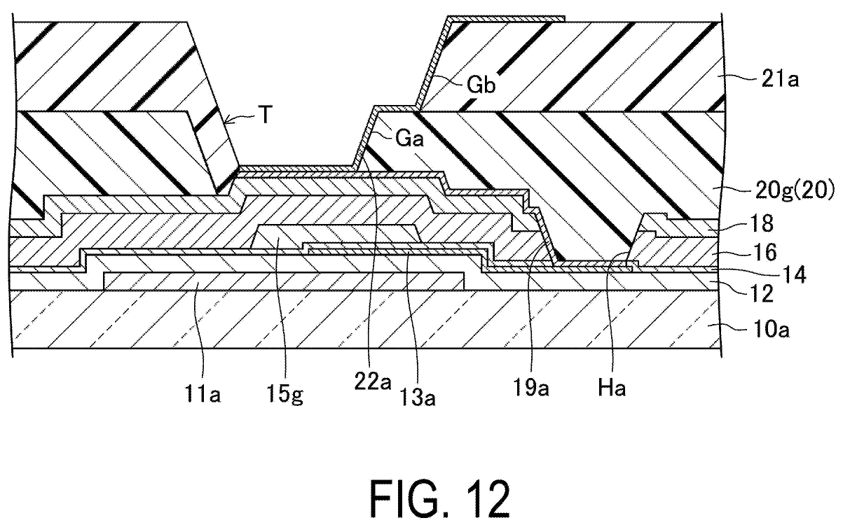

Thereafter, a transparent conductive film such as an ITO film (with a thickness of about 100 nm) is formed by, for example, a sputtering method on the substrate surface on which the organic resin film 21a is formed, and then the transparent conductive film is patterned, thereby forming the second relay electrode 22a or the like as illustrated in FIG. 12. Here, when the second relay electrode 22a is formed, even when a residue 22r (see FIG. 1) of the transparent conductive film to be the second relay electrode 22a is formed on the base of the first groove Ga, the protrusion T of the organic resin film 21a is disposed between the residues 22r adjacent to each other in the X direction in FIG. 1, and thus, the second relay electrodes 22a adjacent to each other in the X direction in FIG. 1 are not short-circuited via the residue 22r.

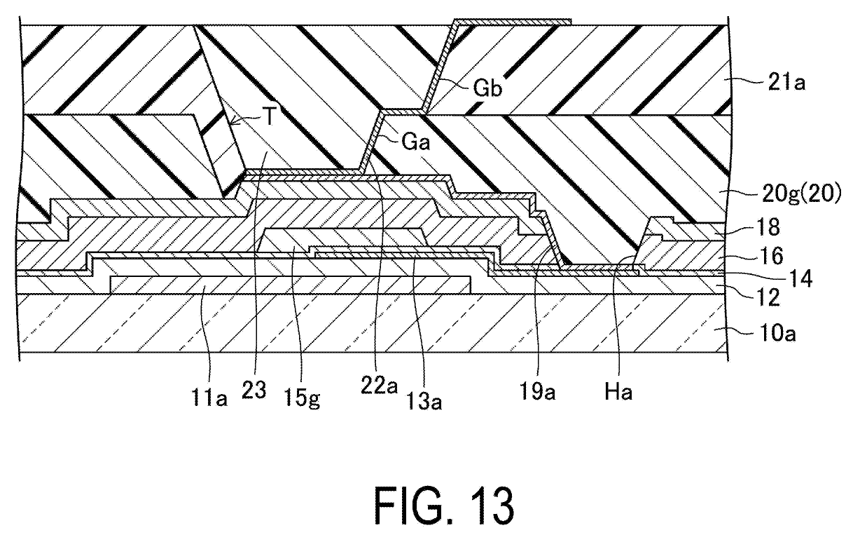

Further, an acrylic photosensitive resin (with a thickness of about 2.5 μm) is applied by, for example, spin coating or slit coating to the substrate surface on which the second relay electrode 22a or the like is formed, and the applied photosensitive resin is partially exposed and then patterned by development, thereby forming the resin-filled layer 23 as illustrated in FIG. 13.

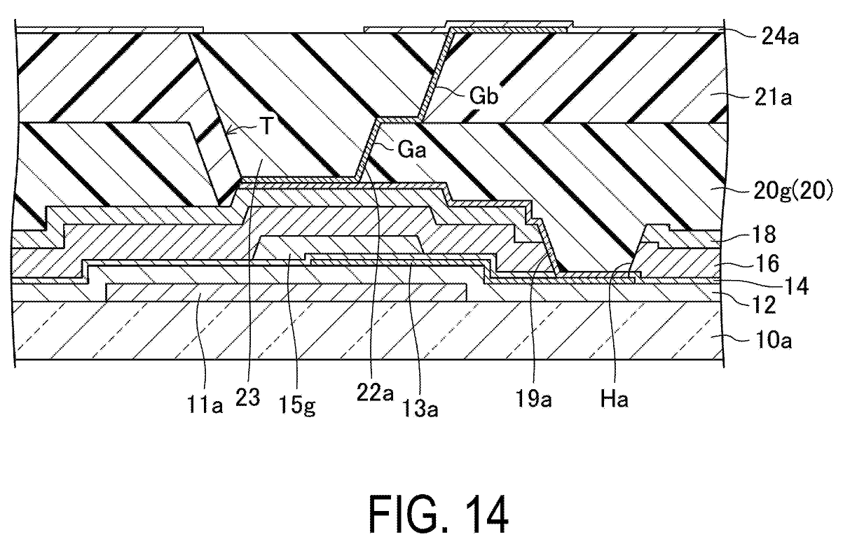

Subsequently, a transparent conductive film such as an ITO film (with a thickness of about 100 nm) is formed by, for example, a sputtering method on the substrate surface on which the resin-filled layer 23 is formed, and then the transparent conductive film is patterned, thereby forming the pixel electrode 24a or the like as illustrated in FIG. 14.

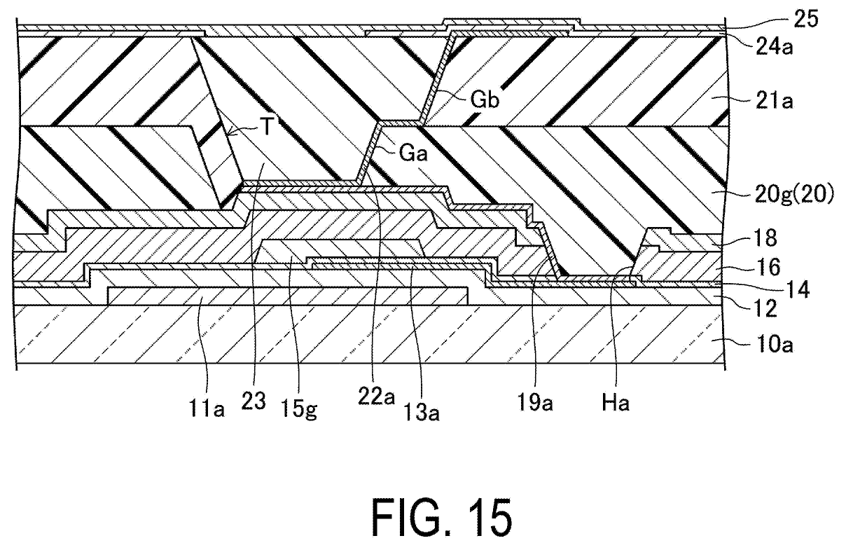

Thereafter, an inorganic insulating film such as a silicon nitride film (with a thickness of about 100 nm) is formed by, for example, plasma CVD on the substrate surface on which the pixel electrode 24a or the like is formed, and then the inorganic insulating film is patterned, thereby forming the third interlayer insulating film 25 as illustrated in FIG. 15.

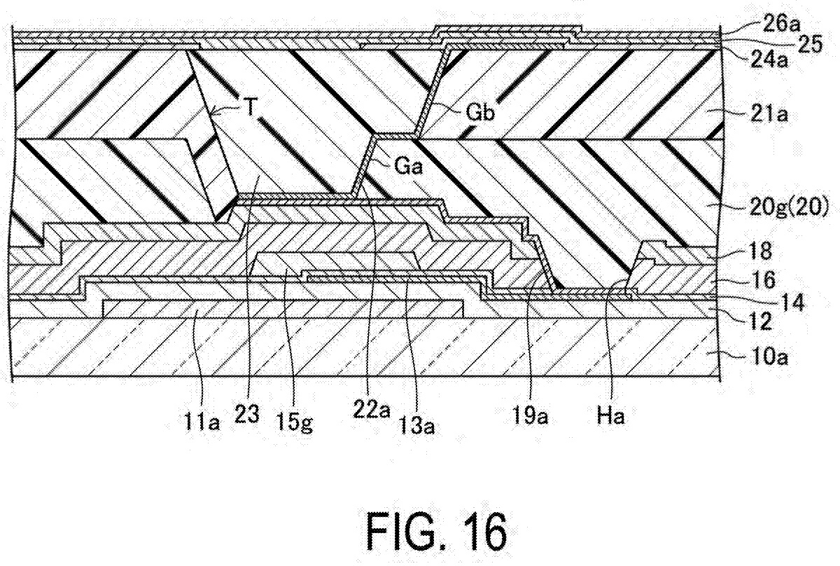

Further, a transparent conductive film such as an ITO film (with a thickness of about 100 nm) is formed by, for example, a sputtering method on the substrate surface on which the third interlayer insulating film 25 is formed, and then the transparent conductive film is patterned, thereby forming the common electrode 26a as illustrated in FIG. 16.

Finally, a polyimide resin film is applied by, for example, a printing method to the entire substrate on which the common electrode 26a is formed, and then the resin film is subjected to baking and rubbing treatment, thereby forming the alignment film 29.

As described above, the active matrix substrate 30a can be manufactured.

Further, the active matrix substrate 30a manufactured as described above and the counter substrate 40 are bonded with a sealing member having a frame-like shape, and a liquid crystal material is sealed between the active matrix substrate 30a and the counter substrate 40 to form the liquid crystal layer 45, thereby manufacturing the liquid crystal display device 50.

As described above, according to the active matrix substrate 30a of the present embodiment and the liquid crystal display device 50 including the active matrix substrate 30a, since the protrusion T protruding toward the one sidewall side of the second groove Gb is provided on the other sidewall of the second groove Gb formed in the organic resin film 21a for each subpixel P, even when the residue 22r of the transparent conductive film to be the second relay electrode 22a is formed on the other sidewall side of the base of the first groove Ga when the second relay electrode 22a is formed, the protrusion T of the organic resin film 21a is disposed between the residues 22r adjacent to each other. Accordingly, since the second relay electrodes 22a adjacent to each other are not short-circuited via the residue 22r, electrical connection of the TFT 5 to the pixel electrode 24a can be reliably performed.

### Second Embodiment

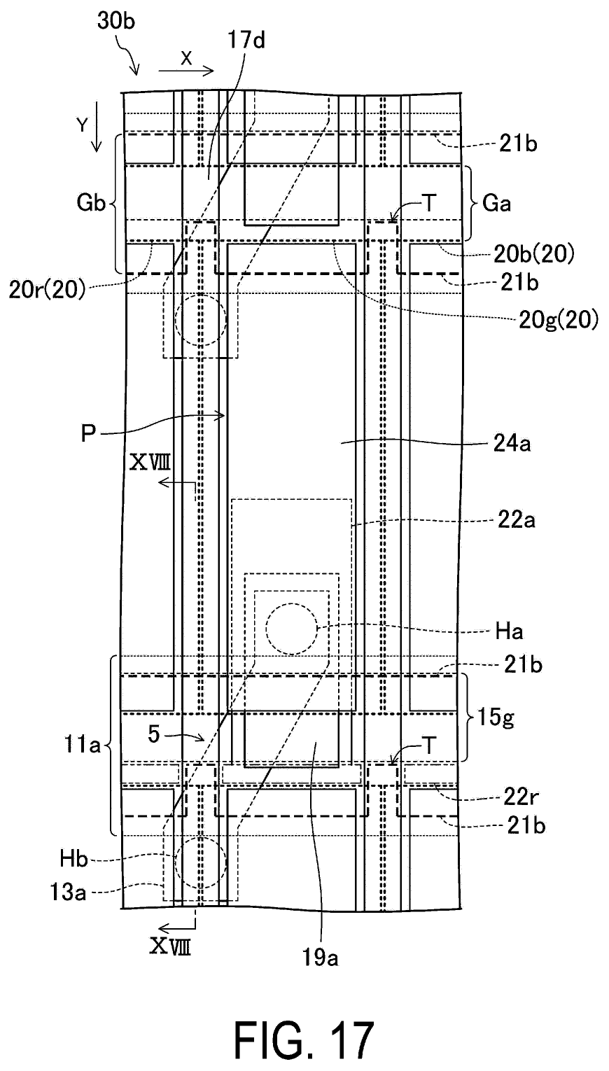

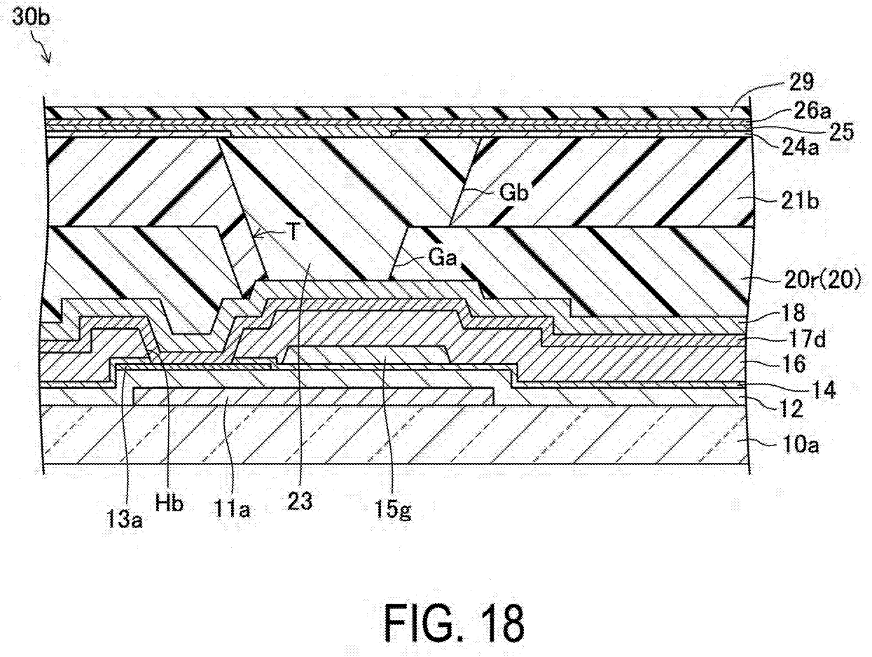

FIGS. 17-30 illustrates a second embodiment of a liquid crystal display device according to the disclosure. FIG. 17 is a plan view of an active matrix substrate 30b according to the present embodiment, corresponding to FIG. 1 of the first embodiment described above. FIG. 18 is a cross-sectional view of the active matrix substrate 30b taken along a line XVIII-XVIII in FIG. 17. Note that, in the following embodiments, portions identical to those in FIGS. 1-16 are denoted by the same reference signs, and their detailed descriptions are omitted.

The liquid crystal display device according to the present embodiment includes the active matrix substrate 30b having a COA structure, a counter substrate 40 provided so as to face the active matrix substrate 30b, and a liquid crystal layer 45 provided between the active matrix substrate 30b and the counter substrate 40. In the liquid crystal display device according to the present embodiment, a plurality of subpixels P (see FIG. 17) are provided in a matrix shape in a display region that displays an image, as in the liquid crystal display device 50 according to the first embodiment. In the display region, as in the liquid crystal display device 50 according to the first embodiment, as illustrated in FIG. 17, subpixels P for gray scale display of red with red layers 20r, subpixels P for gray scale display of green with green layers 20g, and subpixels P for gray scale display of blue with blue layers 20b are disposed adjacent to each other. In the active matrix substrate 30b of FIG. 17, as described above, the plurality of subpixels P are provided in the matrix shape, and an X direction in the drawing is a row direction, and a Y direction in the drawing is a column direction.

As illustrated in FIG. 18, the active matrix substrate 30b includes a base substrate 10a such as a glass substrate, a plurality of TFTs 5 provided on the base substrate 10a so as to correspond to the plurality of subpixels P, a color filter 20 provided on the plurality of TFTs 5 with a first interlayer insulating film 16 and a second interlayer insulating film 18 interposed therebetween, an organic resin film 21b provided on the color filter 20, a plurality of pixel electrodes 24a provided on the organic resin film 21b to correspond to the plurality of subpixels P, a common electrode 26a provided on each pixel electrode 24a with a third interlayer insulating film 25 interposed therebetween, and an alignment film 29 provided on the common electrode 26a. As in the active matrix substrate 30a of the first embodiment described above, as illustrated in FIG. 17, the active matrix substrate 30b includes, on the base substrate 10a in the display region, the plurality of gate lines 15g provided to extend in parallel to each other in the X direction in the drawing to correspond to the plurality of subpixels P arranged in the Y direction in the drawing, and the plurality of source lines 17d provided to extend in parallel to each other in the Y direction in the drawing to correspond to the plurality of subpixels P arranged in the X direction in the drawing, so as to intersect the gate lines 15g with the first interlayer insulating film 16 (see FIG. 18) interposed therebetween.

The organic resin film 21b is made of, for example, a transparent organic resin material such as an acrylic resin. As illustrated in FIGS. 17 and 18, the organic resin film 21b includes the plurality of second grooves Gb formed so as to extend in parallel to each other in the X direction in FIG. 17 to correspond to the plurality of subpixels P arranged in the Y direction in FIG. 17. Here, as illustrated in FIGS. 17 and 18, each second groove Gb is provided so as to overlap each gate line 15g. In each subpixel P, as illustrated in FIG. 17, the drain region of the semiconductor layer 13a constituting the TFT 5 is electrically connected to the pixel electrode 24a via the first relay electrode 19a provided so as to reach the base of the first groove Ga from the base of a first contact hole Ha formed in the gate insulating film 14 and the first interlayer insulating film 16, and the second relay electrode 22a provided so as to reach one edge portion (on the negative side in the Y direction in FIG. 1) of the second groove Gb from the base of the first groove Ga via one sidewall (on the negative side in the Y direction in the drawing) of the first groove Ga and one sidewall (on the negative side in the Y direction in the drawing) of the second groove Gb. Here, as illustrated in FIGS. 17 and 18, the protrusion T protruding toward one sidewall side (on the negative side in the Y direction in FIG. 17) of the second groove Gb is provided on the other sidewall (on the positive side in the Y direction in FIG. 17) of the second groove Gb for each subpixel P. As illustrated in FIG. 17, the protrusion T is provided in a narrow rectangular protruding shape in a plan view so as to overlap each source line 17d.

As illustrated in FIGS. 17 and 18, in each subpixel P, the pixel electrode 24a is provided in a rectangular shape on the organic resin film 21b and the resin-filled layer 23 formed inside the first groove Ga and the second groove Gb.

In the liquid crystal display device of the present embodiment, as in the liquid crystal display device 50 of the first embodiment, a predetermined voltage is applied to the liquid crystal layer 45 disposed between each pixel electrode 24a and the common electrode 26a and to the auxiliary capacity, and the alignment state of the liquid crystal layer 45 is changed by an electrical field generated in a direction along the surface of the substrate, that is, in a transverse direction, thereby adjusting the transmittance of light passing through the panel of each subpixel P to display images.

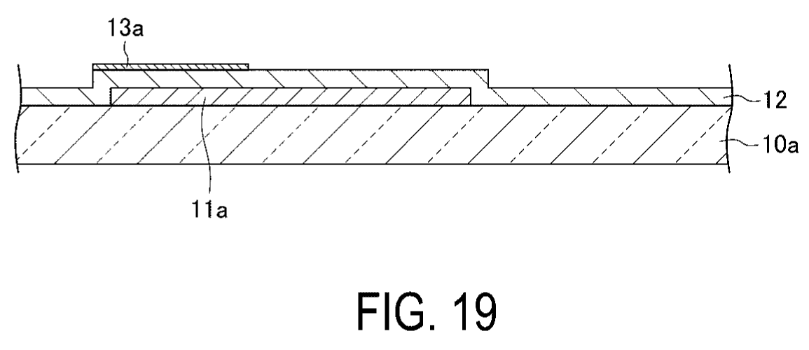

Next, a manufacturing method of the liquid crystal display device of the present embodiment will be described, focusing on a method of manufacturing the active matrix substrate 30b. FIGS. 19-30 are first to twelfth cross-sectional views, respectively, sequentially illustrating a part of a manufacturing method of the active matrix substrate 30b.

First, a metal film such as a titanium film (with a thickness of about 50 nm) or the like is formed by, for example, a sputtering method on the base substrate 10a such as a glass substrate, and then the metal film is patterned, thereby forming the light blocking layer 11a (see FIG. 19) or the like.

Subsequently, a silicon oxide film (with a thickness of about 100 nm) or the like is formed by, for example, plasma chemical vapor deposition (CVD) on the substrate surface on which the light blocking layer 11a or the like is formed, thereby forming the base coat film 12 (see FIG. 19).

Thereafter, InGaZnO₄ (with a thickness of about 30 nm) or the like is formed by, for example, a sputtering method on the substrate surface on which the base coat film 12 is formed, to form a semiconductor film made of an oxide semiconductor, and then the semiconductor film is patterned, thereby forming the semiconductor layer 13a or the like as illustrated in FIG. 19.

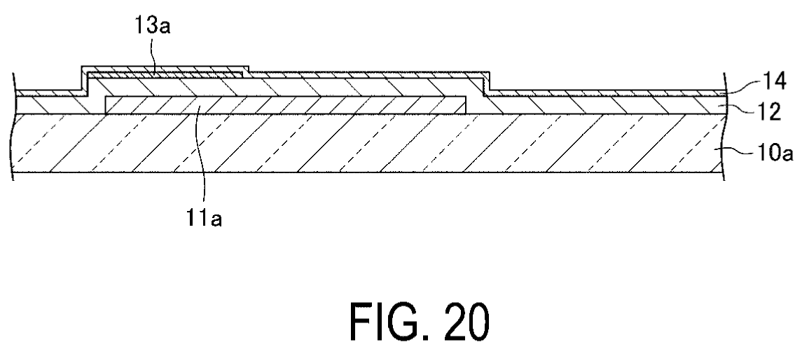

Further, an inorganic insulating film such as a silicon oxide film (with a thickness of about 100 nm) is formed by, for example, plasma CVD on the substrate surface on which the semiconductor layer 13a or the like is formed and then the inorganic insulating film is patterned, thereby forming the gate insulating film 14 as illustrated in FIG. 20.

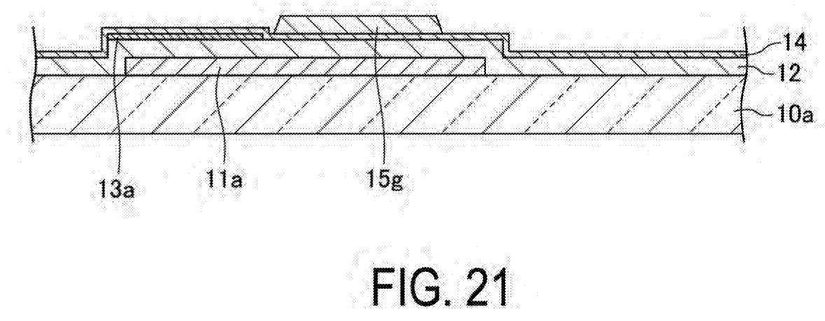

Subsequently, a titanium film (with a thickness of about 50 nm), an aluminum film (with a thickness of approximately 300 nm), and a titanium film (with a thickness of approximately 50 nm) are sequentially formed by, for example, a sputtering method on the substrate surface on which the gate insulating film 14 is formed to form a metal layered film, and then the metal layered film is patterned, thereby forming the gate line (gate electrode) 15g or the like as illustrated in FIG. 21.

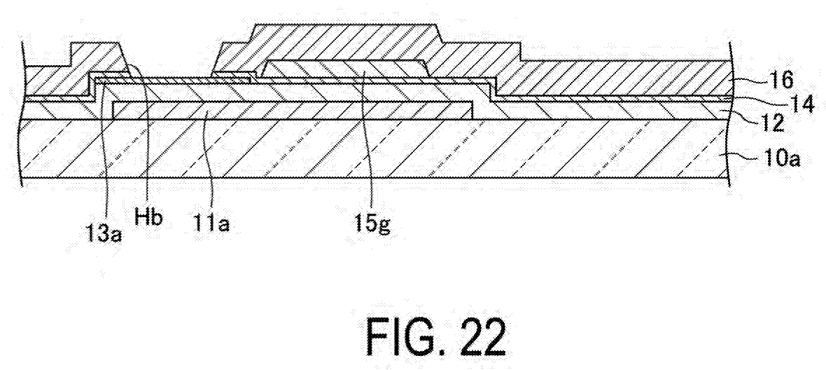

Thereafter, a silicon oxide film (with a thickness of about 300 nm) and a silicon nitride film (with a thickness of about 150 nm) are sequentially formed by, for example, plasma CVD on the substrate surface on which the gate line 15g or the like is formed to form an inorganic insulating layered film, and then the inorganic insulating layered film is patterned, thereby forming the first interlayer insulating film 16 (and the gate insulating film 14) including the first contact hole Ha (see FIG. 17) and the second contact hole Hb as illustrated in FIG. 22.

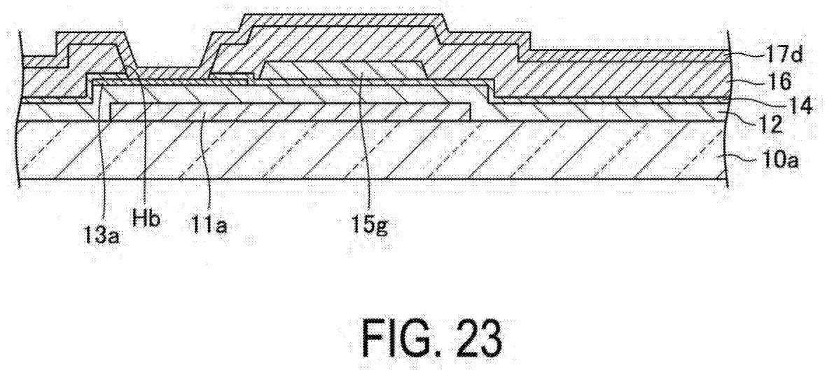

Further, a titanium film (with a thickness of about 50 nm), an aluminum film (with a thickness of about 300 nm), and a titanium film (with a thickness of about 50 nm) are sequentially formed by, for example, a sputtering method on the substrate surface on which the first interlayer insulating film 16 is formed to form a metal layered film, and then, the metal layered film is patterned, thereby forming the source line 17d or the like as illustrated in FIG. 23.

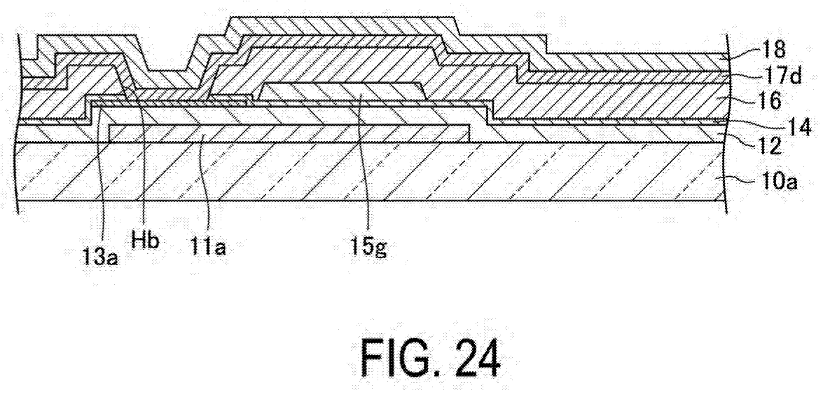

Subsequently, a silicon oxide film (with a thickness of about 300 nm) and a silicon nitride film (with a thickness of about 150 nm) are sequentially formed by, for example, plasma CVD on the substrate surface on which the source line 17d or the like is formed to form an inorganic insulating layered film, and then the inorganic insulating layered film is patterned, thereby forming the second interlayer insulating film 18 including the first contact hole Ha (see FIG. 17) as illustrated in FIG. 24.

Thereafter, a transparent conductive film such as an indium tin oxide ((hereinafter, also referred to as “ITO”) film (with a thickness of about 100 nm) is formed by, for example, a sputtering method on the substrate surface on which the second interlayer insulating film 18 is formed, and then the transparent conductive film is patterned, thereby forming the first relay electrode 19a (see FIG. 17) or the like.

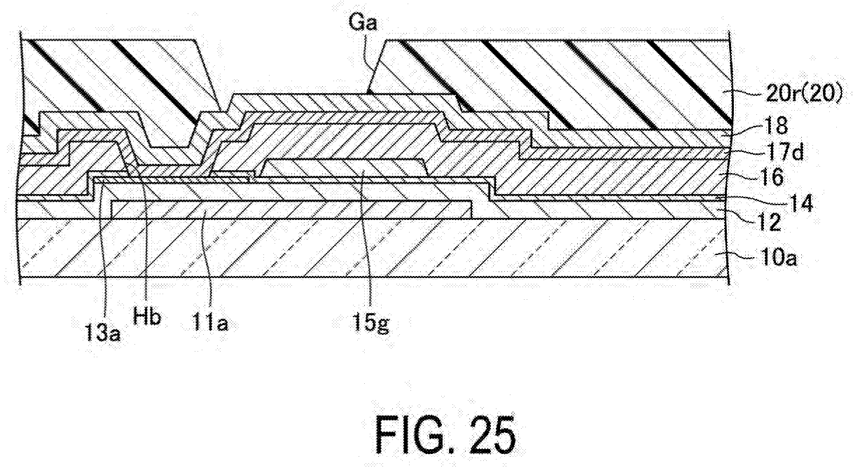

Further, a red, green, or blue colored acrylic photosensitive resin is applied by, for example, spin coating or slit coating to the substrate surface on which the first relay electrode 19a or the like is formed, and the applied photosensitive resin is partially exposed and then patterned by development, thereby forming a colored layer (for example, the red layer 20r) having a selected color with a thickness of about 1.5 μm. Thereafter, the same or a similar step is repeated for the other two colors to form the colored layers of the other two colors (for example, the green layer 20g and the blue layer 20b), thereby forming the color filter 20 including the first groove Ga as illustrated in FIG. 25.

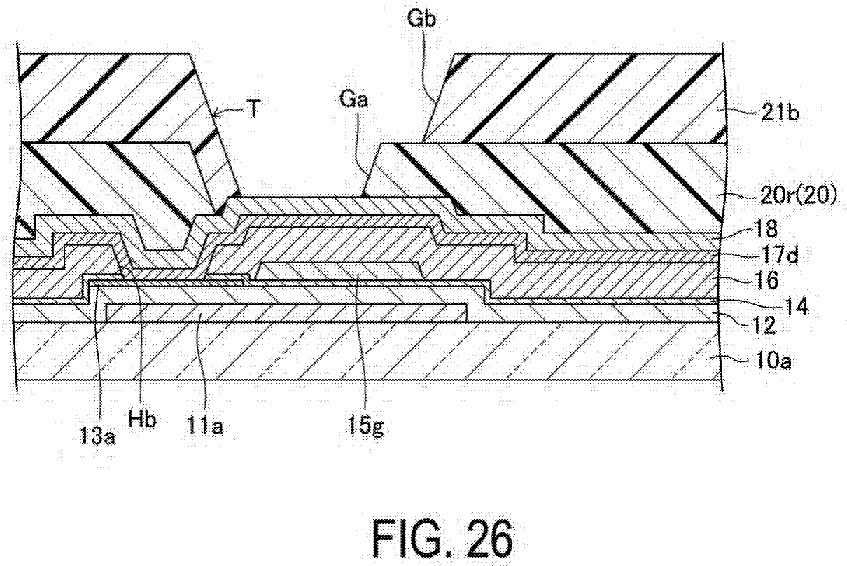

Subsequently, an acrylic photosensitive resin is applied by, for example, spin coating or slit coating to the substrate surface on which the color filter 20 is formed, and the applied photosensitive resin is partially exposed and then patterned by development, thereby forming the organic resin film 21b including the second groove Gb provided with the protrusion T with a thickness of about 2.0 μm as illustrated in FIG. 26.

Thereafter, a transparent conductive film such as an ITO film (with a thickness of about 100 nm) is formed by, for example, a sputtering method on the substrate surface on which the organic resin film 21b is formed, and then the transparent conductive film is patterned, thereby forming the second relay electrode 22a (see FIG. 17) or the like. Here, when the second relay electrode 22a is formed, even when a residue 22r (see FIG. 17) of the transparent conductive film to be the second relay electrode 22a is formed on the base of the first groove Ga, the protrusion T of the organic resin film 21b is disposed between the residues 22r adjacent to each other in the X direction in FIG. 17, and thus, the second relay electrodes 22a adjacent to each other in the X direction in FIG. 17 are not short-circuited via the residue 22r.

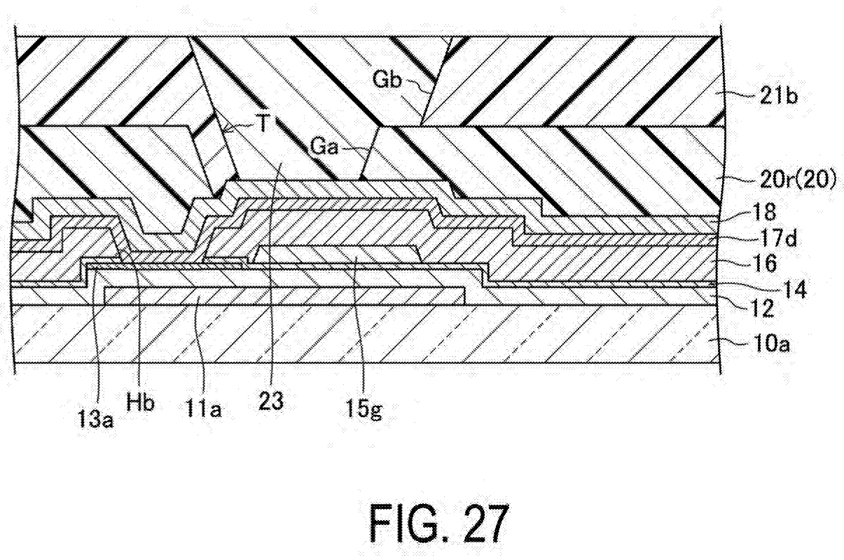

Further, an acrylic photosensitive resin (with a thickness of about 2.5 μm) is applied by, for example, spin coating or slit coating to the substrate surface on which the second relay electrode 22a or the like is formed, and the applied photosensitive resin is partially exposed and then patterned by development, thereby forming the resin-filled layer 23 as illustrated in FIG. 27.

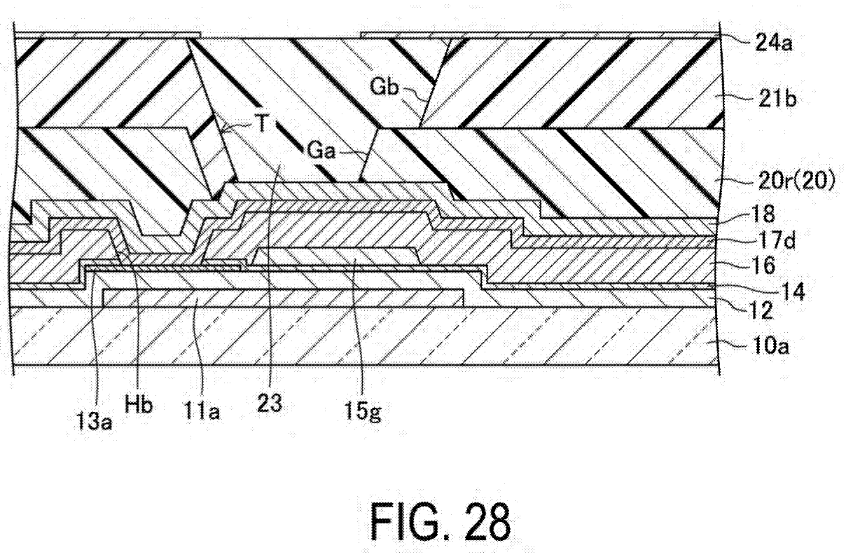

Subsequently, a transparent conductive film such as an ITO film (with a thickness of about 100 nm) is formed by, for example, a sputtering method on the substrate surface on which the resin-filled layer 23 is formed, and then the transparent conductive film is patterned, thereby forming the pixel electrode 24a or the like as illustrated in FIG. 28.

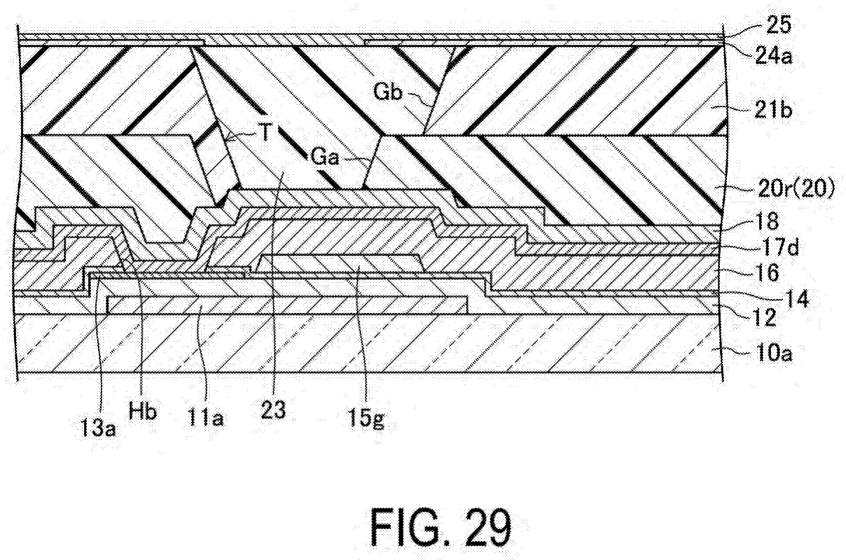

Thereafter, an inorganic insulating film such as a silicon nitride film (with a thickness of about 100 nm) is formed by, for example, plasma CVD on the substrate surface on which the pixel electrode 24a or the like is formed, and then the inorganic insulating film is patterned, thereby forming the third interlayer insulating film 25 as illustrated in FIG. 29.

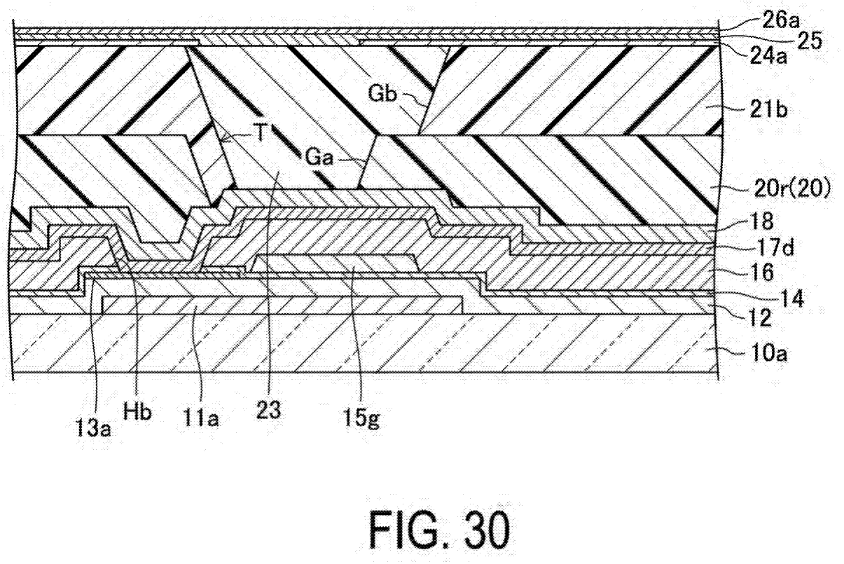

Further, a transparent conductive film such as an ITO film (with a thickness of about 100 nm) is formed by, for example, a sputtering method on the substrate surface on which the third interlayer insulating film 25 is formed, and then the transparent conductive film is patterned, thereby forming the common electrode 26a as illustrated in FIG. 30.

Finally, a polyimide resin film is applied by, for example, a printing method to the entire substrate on which the common electrode 26a is formed, and then the resin film is subjected to baking and rubbing treatment, thereby forming the alignment film 29.

As described above, the active matrix substrate 30b can be manufactured.

Further, the active matrix substrate 30b manufactured as described above and the counter substrate 40 are bonded with a sealing member having a frame-like shape, and a liquid crystal material is sealed between the active matrix substrate 30a and the counter substrate 40 to form the liquid crystal layer 45, thereby manufacturing the liquid crystal display device of the present embodiment.

As described above, according to the active matrix substrate 30b of the present embodiment and the liquid crystal display device including the active matrix substrate 30b, since the protrusion T protruding toward the one sidewall side of the second groove Gb is provided on the other sidewall of the second groove Gb formed in the organic resin film 21b for each subpixel P, even when the residue 22r of the transparent conductive film to be the second relay electrode 22a is formed on the other sidewall side of the base of the first groove Ga when the second relay electrode 22a is formed, the protrusion T of the organic resin film 21b is disposed between the residues 22r adjacent to each other. Accordingly, since the second relay electrodes 22a adjacent to each other are not short-circuited via the residue 22r, electrical connection of the TFT 5 to the pixel electrode 24a can be reliably performed.

### Third Embodiment

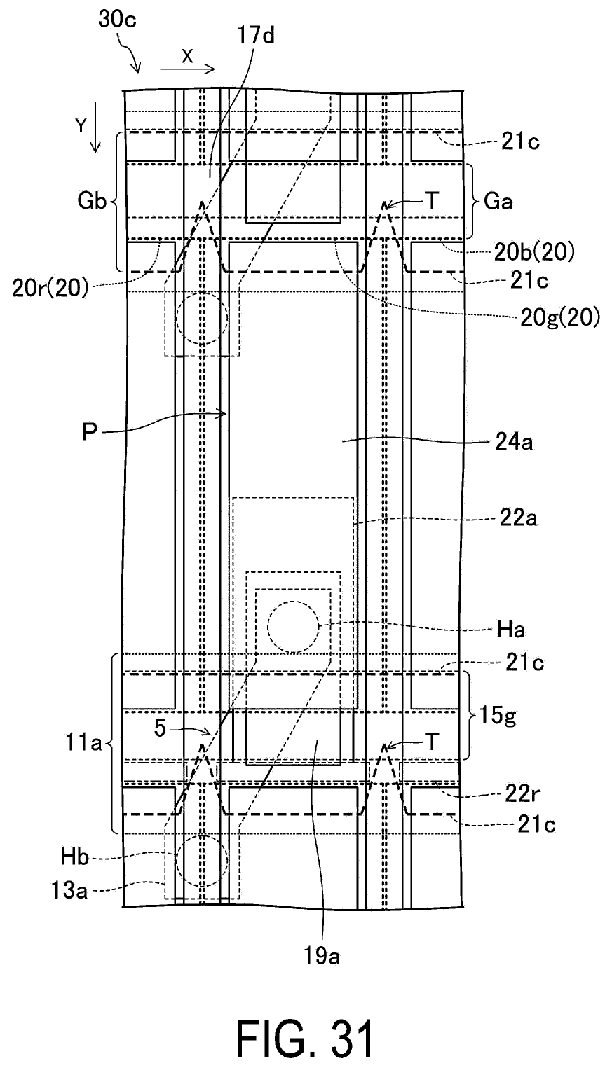

FIG. 31 illustrates a third embodiment of the liquid crystal display device according to the disclosure. FIG. 31 is a plan view of an active matrix substrate 30c according to the present embodiment, corresponding to FIG. 1 of the first embodiment described above.

The liquid crystal display device according to the present embodiment includes the active matrix substrate 30c having a COA structure, a counter substrate 40 provided so as to face the active matrix substrate 30c, and a liquid crystal layer 45 provided between the active matrix substrate 30b and the counter substrate 40. In the liquid crystal display device according to the present embodiment, a plurality of subpixels P (see FIG. 31) are provided in a matrix shape in a display region that displays an image, as in the liquid crystal display device 50 according to the first embodiment. In the display region, as in the liquid crystal display device 50 according to the first embodiment, as illustrated in FIG. 31, subpixels P for gray scale display of red with red layers 20r, subpixels P for gray scale display of green with green layers 20g, and subpixels P for gray scale display of blue with blue layers 20b are disposed adjacent to each other. In the active matrix substrate 30c of FIG. 31, as described above, the plurality of subpixels P are provided in the matrix shape, and an X direction in the drawing is a row direction, and a Y direction in the drawing is a column direction.

The active matrix substrate 30c includes a base substrate 10a such as a glass substrate, a plurality of TFTs 5 provided on the base substrate 10a so as to correspond to the plurality of subpixels P, a color filter 20 provided on the plurality of TFTs 5 with a first interlayer insulating film 16 and a second interlayer insulating film 18 interposed therebetween, an organic resin film 21c provided on the color filter 20, a plurality of pixel electrodes 24a provided on the organic resin film 21c to correspond to the plurality of subpixels P, a common electrode 26a provided on each pixel electrode 24a with a third interlayer insulating film 25 interposed therebetween, and an alignment film 29 provided on the common electrode 26a. As in the active matrix substrate 30a of the first embodiment described above, as illustrated in FIG. 17, the active matrix substrate 30c includes, on the base substrate 10a in the display region, the plurality of gate lines 15g provided to extend in parallel to each other in the X direction in the drawing to correspond to the plurality of subpixels P arranged in the Y direction in the drawing, and the plurality of source lines 17d provided to extend in parallel to each other in the Y direction in the drawing to correspond to the plurality of subpixels P arranged in the X direction in the drawing, so as to intersect the gate lines 15g with the first interlayer insulating film 16 (see FIG. 18) interposed therebetween.

The organic resin film 21c is made of, for example, a transparent organic resin material such as an acrylic resin. As illustrated in FIG. 31, the organic resin film 21c includes a plurality of second grooves Gb formed so as to extend in parallel to each other in the X direction in the drawing to correspond to the plurality of subpixels P arranged in the Y direction in the drawing. Here, as illustrated in FIG. 31, each second groove Gb is provided so as to overlap each gate line 15g. In each subpixel P, as illustrated in FIG. 31, the drain region of the semiconductor layer 13a constituting the TFT 5 is electrically connected to the pixel electrode 24a via the first relay electrode 19a provided so as to reach the base of the first groove Ga from the base of a first contact hole Ha formed in the gate insulating film 14 and the first interlayer insulating film 16, and the second relay electrode 22a provided so as to reach one edge portion (on the negative side in the Y direction in the drawing) of the second groove Gb from the base of the first groove Ga via one sidewall (on the negative side in the Y direction in the drawing) of the first groove Ga and one sidewall (on the negative side in the Y direction in the drawing) of the second groove Gb. Here, as illustrated in FIG. 31, the protrusion T protruding toward one sidewall side (on the negative side in the Y direction in the drawing) of the second groove Gb is provided on the other sidewall (on the positive side in the Y direction in the drawing) of the second groove Gb for each subpixel P. As illustrated in FIG. 31, the protrusion T is provided in a tapered shape of a narrow inverted V shape in a plan view so as to overlap each source line 17d.

As illustrated in FIG. 31, in each subpixel P, the pixel electrode 24a is provided in a rectangular shape on the organic resin film 21c and a resin-filled layer 23 formed inside the first groove Ga and the second groove Gb.

In the liquid crystal display device of the present embodiment, as in the liquid crystal display device 50 of the first embodiment, a predetermined voltage is applied to the liquid crystal layer 45 disposed between each pixel electrode 24a and the common electrode 26a and to the auxiliary capacity, and the alignment state of the liquid crystal layer 45 is changed by an electrical field generated in a direction along the surface of the substrate, that is, in a transverse direction, thereby adjusting the transmittance of light passing through the panel of each subpixel P to display images.

The active matrix substrate 30c of the present embodiment can be manufactured by changing a shape on a tip side of the protrusion T of the second groove Gb formed in the organic resin film 21b in the manufacturing method of the active matrix substrate 30b of the second embodiment described above.

As described above, according to the active matrix substrate 30c of the present embodiment and the liquid crystal display device including the active matrix substrate 30c, since the protrusion T protruding toward the one sidewall side of the second groove Gb is provided on the other sidewall of the second groove Gb formed in the organic resin film 21c for each subpixel P, even when the residue 22r of the transparent conductive film to be the second relay electrode 22a is formed on the other sidewall side of the base of the first groove Ga when the second relay electrode 22a is formed, the protrusion T of the organic resin film 21c is disposed between the residues 22r adjacent to each other. Accordingly, since the second relay electrodes 22a adjacent to each other are not short-circuited via the residue 22r, electrical connection of the TFT 5 to the pixel electrode 24a can be reliably performed.

### Other Embodiments

In each of the embodiments described above, the liquid crystal display device including the active matrix substrate provided with the TFT including the semiconductor layer formed of the oxide semiconductor film is exemplified. However, the disclosure is also applicable to a liquid crystal display device including an active matrix substrate provided with a TFT including a semiconductor layer formed of a polysilicon film of low temperature polysilicon (LTPS), an amorphous silicon film, or the like.

Additionally, in each of the embodiments described above, the liquid crystal display device including the active matrix substrate in which the electrodes of the TFTs connected to the pixel electrodes serve as drain electrodes is exemplified. However, the disclosure is also applicable to a liquid crystal display device including an active matrix substrate in which the electrodes of the TFTs connected to the pixel electrodes serve as source electrodes.

### Industrial Aplicability

As described above, the disclosure is useful for the liquid crystal display device of the in-plane switching mode including the active matrix substrate having a color filter-on-array structure.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

1. An Active matrix substrate comprising:
a base substrate;
a plurality of thin film transistors provided to correspond to a plurality of subpixels arranged in a matrix on the base substrate;
a color filter provided on the plurality of thin film transistors with a first inorganic insulating film interposed between the color filter and the plurality of thin film transistors and including a colored layer of a predetermined color disposed to correspond to each subpixel;
an organic resin film provided on the color filter;
a plurality of pixel electrodes provided on the organic resin film to correspond to the plurality of subpixels; and
a common electrode provided on pixel electrodes with a second inorganic insulating film interposed between the common electrode and the pixel electrodes,
wherein the color filter includes a plurality of first grooves formed to extend in parallel to each other in the row direction to correspond to a plurality of subpixels arranged in the column direction,
the organic resin film includes a plurality of second grooves formed to extend in parallel to each other in a row direction to correspond to a plurality of subpixels arranged in a column direction,
in each subpixel, the corresponding thin film transistor is electrically connected to the corresponding pixel electrode via a first relay electrode provided to reach a base of the corresponding first groove from a base of a contact hole formed in the first inorganic insulating film, and a second relay electrode provided to reach one edge portion of the corresponding second groove from the base of the corresponding first groove via one sidewall of the first groove and one sidewall of the corresponding second groove, and
a protrusion protruding toward the one sidewall side of the second groove is provided on the other sidewall of the second groove for each subpixel.

2. The active matrix substrate according to claim 1, further comprising:
a plurality of source lines provided to extend in parallel to each other in the column direction to correspond to a plurality of subpixels arranged in the row direction,
wherein the protrusion is provided between a pair of source lines adjacent to each other in the plurality of source lines.

3. The active matrix substrate according to claim 1, further comprising:
a plurality of source lines provided to extend in parallel to each other in the column direction to correspond to a plurality of subpixels arranged in the row direction,
wherein the protrusion is provided to overlap a corresponding source line of the plurality of source lines.

4. The active matrix substrate according to claim 3,
wherein the protrusion is provided in a tapered shape in a plan view.

5. The active matrix substrate according to claim 1, further comprising:
a plurality of gate lines provided to extend in parallel to each other in the row direction to correspond to a plurality of subpixels arranged in the column direction,
wherein in each subpixel, the corresponding first groove and the corresponding second groove are provided to overlap the corresponding gate line.

6. A liquid crystal display device comprising:
the active matrix substrate according to claim 1;
a counter substrate provided to face the active matrix substrate; and
a liquid crystal layer provided between the active matrix substrate and the counter substrate.
